(19) United States
(12) Patent Application Publication
(10) Pub. No.: US 2022/0213616 A1
(43) Pub. Date: Jul. 7, 2022

(54) METHOD AND CRUCIBLE FOR PRODUCING PARTICLE-FREE AND NITROGEN-FREE SILICON INGOTS BY MEANS OF TARGETED SOLIDIFICATION, SILICON INGOT, AND THE USE OF THE CRUCIBLE

(71) Applicant: FRAUNHOFER-GESELLSCHAFT ZUR FÖRDERUNG DER ANGEWANDTEN FORSCHUNG E. V., München (DE)

(72) Inventors: Christian REIMANN, Erlangen (DE); Matthias TREMPA, Erlangen (DE); Stanislaus SCHWANKE, Erlangen (DE); Christian KRANERT, Erlangen (DE); Jochen FRIEDRICH, Erlangen (DE)

(73) Assignee: FRAUNHOFER-GESELLSCHAFT ZUR FÖRDERUNG DER ANGEWANDTEN FORSCHUNG E. V., München (DE)

(21) Appl. No.: 17/608,627

(22) PCT Filed: May 5, 2020
(86) PCT No.: PCT/EP2020/062408

§ 371 Date: Nov. 3, 2021

(30) Foreign Application Priority Data
May 6, 2019 (DE) 10 2019 206 489.2

(51) Int. Cl. C30B 29/06; C30B 35/00

(52) U.S. Cl. CPC C30B 29/06; C30B 35/002

(57) ABSTRACT

The present invention relates to a method and to a crucible for producing particle-free and nitrogen-free silicon ingots by means of targeted solidification, in which method a crucible is provided, the inner surface of the crucible having a coating containing SiₓN_{y} over its full surface or at least in regions, which coating is coated with a protective layer containing SiOₓ in order to reduce or prevent the introduction of nitrogen and SiₓN_{y} particles into the silicon. The invention also relates to a silicon ingot, which is virtually free from nitrogen or SiₓN_{y} particles.

The present invention relates to a method and a crucible for producing particle-free and nitrogen-free silicon ingots by means of directional solidification, in which a crucible is provided, wherein the inner surface of the crucible has a coating containing SiₓN_{y} (particularly Si₃N₄) over the entire surface or at least in regions, which coating is coated with a protective layer containing SiOₓ (with 1≤x≤2) for reducing or avoiding the entry of nitrogen and SiₓN_{y} particles into the silicon. The invention also relates to a silicon ingot that is virtually free of nitrogen or SiₓN_{y} particles.

Monocrystalline silicon is very suitable for use as a mirror substrate due to its physical properties. The method of directional solidification can be considered here for producing large silicon blocks, from which components such as mirror substrates having dimensions of approx. 90×60×20 cm³ (L×W×H) can be prepared, which method so far has been used almost exclusively for producing multicrystalline or quasi-single crystalline silicon blocks for use in photovoltaics. Processes for producing silicon monocrystals that are otherwise widespread, such as the Czochralski process or the floating zone process, are ruled out from the outset due to the limited crystal dimensions.

The technology of producing quasi-monocrystalline silicon blocks by means of directional solidification is established (quasi-mono technology). Here, monocrystalline silicon plates are placed on the bottom of the crucible, from which the monocrystalline block is solidified in the crucible. The term quasi-monocrystalline comes from the fact that multicrystalline growth occurs in the outermost edge area of the silicon blocks.

A process-related problem, however, is nitrogen and carbon contamination of the silicon melt. The nitrogen is introduced into the SiₓN_{y} crucible coating (SiₓN_{y} particles) by the silicon melt through chemical dissolution and mechanical erosion. Most of the carbon gets into the silicon melt via the furnace atmosphere. In both cases, when the solubility limits are exceeded in the silicon melt, SiC or SiₓN_{y} particles are formed, which are then incorporated into the crystal during the crystallization process. In addition, SiC and SiₓN_{y} precipitates can form in the solidified silicon as a result of diffusion processes. Experience has shown that the diameter of such particles is in the range from a few micrometers to approx. 50 μm. In addition, SiC filaments or SiₓN_{y} needles, the cross-section of which is in a similar range to the particles, can be up to several millimeters in length. During the conditioning process of the component surfaces (polishing), these particles cause scratch structures on the surface when they are torn out of the surface or leave behind hole-like depressions.

Accordingly, these particles/precipitates in the silicon material must be kept very small (nm range) or completely avoided in order to be able to produce the above-mentioned silicon components, particularly mirror substrates, with the required surface quality.

Some technological approaches that address this problem are already known from the PV industry. For example, an argon countercurrent can thus be built up over the silicon melt surface via a suitable gas management system, which countercurrent reduces the entry of gaseous carbon monoxide (CO) into the silicon melt and thus the formation of SiC precipitates (WO 2009100694 A1). However, the introduction of carbon cannot be completely avoided in this way, so that there is always a certain residual risk of SiC formation in the melt or the crystal.

It is further known that the use of electromagnetic fields can influence the melt convection such that any supersaturation of nitrogen or carbon in front of the silicon crystal growth front is broken down into the less contaminated melt volume in a short time before SiC or SiₓN_{y} precipitation occurs (DE102010041061 B4). This indirect method for avoiding the SiC and Si₃N₄ precipitations is very effective, but not trivial, relatively expensive and, for geometric reasons, cannot be applied to any crystallization furnace. In addition, with the quasi-mono process, care must be taken that excessive convection of the melt does not melt the seed plates on the bottom of the crucible too strongly or unevenly, which makes it difficult to use electromagnetic stirring for this technology.

However, the measures mentioned do not prevent the introduction of nitrogen/SiₓN_{y} particles through contact of the SiₓN_{y} coating with the silicon melt.

Based on this, it was the object of the present invention to provide a method for producing silicon ingots, wherein the silicon ingots are essentially free of nitrogen and SiₓN_{y} particles.

This object is achieved using the method having the features of claim 1, the crucible having the features of claim 18 and the silicon ingot having the features of claim 25. Claim 29 specifies a use according to the invention.

According to the invention, a method for producing particle-free and nitrogen-free silicon ingots by means of directional solidification is provided, in which
a) a crucible is provided, wherein the inner surface of the crucible has a coating containing SiₓN_{y} over the entire surface or at least in regions, which coating is coated with a protective layer containing SiOₓ (with 1×2) for reducing or avoiding nitrogen entry and SiₓN_{y} particle entry into the silicon,
b) the crucible is filled with silicon raw material,
c) the silicon raw material is melted in the crucible to form a silicon melt, and
d) the silicon melt is subjected to a directional solidification, whereby particle-free and nitrogen-free silicon is formed.

Surprisingly, it was found that the entry of nitrogen and SiₓN_{y} (particularly Si₃N₄) can be prevented or at least significantly reduced by applying an additional protective layer to the surface of the SiₓN_{y} crucible coating. This protective layer as such consists of, essentially consists of or contains highly pure nano- or micrometer-sized SiOₓ particles, particularly SiO₂ particles in an aqueous suspension which is sprayed onto the existing SiₓN_{y} layer. The spray parameters are to be selected such that the underlying SiₓN_{y} layer, particularly an Si₃N₄ layer, is not damaged.

The SiOₓ protective layer prevents direct contact of the silicon melt with the SiₓN_{y} coating and thus both the chemical dissolution reaction between silicon and SiₓN_{y} and the direct erosion of the SiₓN_{y} coating due to the movement of the melt. After solidification, the SiOₓ layer forms a solid bond with the silicon block due to its wetting behavior. The separation plane between the block and the crucible is consequently at the boundary between SiOₓ and SiₓN_{y} layer, within the SiₓN_{y} layer or at the interface between SiₓN_{y} layer and crucible (depending on the adhesive properties of the SiₓN_{y} layer used).

It is preferred for the protective layer to be applied to the SiₓN_{y}-containing coating by means of a spraying method, a brushing method, a spreading method and/or a dipping method of a suspension containing SiOₓ and the moist protective layer containing SiOₓ produced in this way to be dried. The suspension preferably contains 5 to 90% by weight SiOₓ, particularly colloidal SiOₓ, and 95 to 10% by weight of a suspending agent, preferably an alcohol or water, particularly preferably deionized water.

A further preferred embodiment provides that the protective layer is applied to the SiₓN_{y}-containing coating by means of a spraying method, a brushing method, a spreading method, and/or a dipping method of a suspension containing Si and the moist protective layer produced in this way containing Si is dried and/or oxidized. The suspension here preferably contains 5 to 90% by weight of Si and 95 to 10% by weight of a suspending agent, preferably an alcohol or water, particularly preferably deionized water. The Si layer is preferably oxidized under an air atmosphere or an inert gas atmosphere enriched with oxygen at a temperature of 800 and 1400° C., preferably at a temperature of 1050 and 1200° C., to form an SiOₓ layer. The duration of the oxidation is preferably in the range from 0.5 h to 12 h.

It is preferred that when the SiOₓ or Si-containing suspension is applied, the crucible or the coating containing SiₓN_{y} has a temperature of 10° C. to 200° C., preferably a temperature of 20° C. to 100° C.

The SiOₓ of the protective layer preferably has at least one of the following properties:
an iron content of 0 ppm to 5 ppm, preferably 0.5 to 2 ppm,
an aluminum content of 0 ppm to 20 ppm, preferably 0.5 to 15 ppm,
a content of metals other than iron and aluminum of 0 ppm to 5 ppm, preferably 0.5 to 2 ppm,
a particle size d50 of 0.05 to 100 μm, preferably 0.5 to 50 μm, particularly preferably 1 to 30 μm,
a particle size d90 of 0.01 to 200 μm, preferably 0.05 to 100 μm, particularly preferably 0.1 to 50 μm.

The particle size can be determined by means of established laser scattering and laser diffraction methods.

The particle size of the SiOₓ must be selected to be very small in order to enable the densest possible layer. Only thus can a sufficient barrier effect against the diffusion of nitrogen through the protective layer be prevented. It was also found that a protective layer made of a monolayer of SiOₓ does not have a sufficient barrier effect, since the arrangement as a monolayer does not allow an adequate barrier effect against diffusion.

The crucible preferably contains or consists of a material which is selected from the group consisting of SiC, C, BN, pBN, SiₓN_{y}, SiOₓ, and mixtures and combinations thereof.

A further preferred embodiment provides that the coating containing SiₓN_{y} has at least one of the following properties:
a content of up to 100% by weight, preferably 60% by weight to 100% by weight, particularly preferably 80% by weight to 100% by weight, SiₓN_{y}
a thickness of 10 μm to 2500 μm, preferably of 100 μm to 1000 μm, particularly preferably of 300 μm to 600 μm,
a square mean roughness value R_{q} of 1 μm to 100 μm, preferably of 5 μm to 20 μm,
an adhesive strength on the crucible bottom of 0.5 MPa to 5 MPa, preferably of 1 MPa to 3 MPa,
a porosity of 0.5% to 60%, preferably of 1% to 40%.

The square mean roughness value R_{q} can be determined from

$${R}_{q} = \sqrt{\frac{1}{{l}_{n}}} {\int }_{0}^{{l}_{n}} {z}^{2} ( x ) dx$$

With lₙ=profile line length and z=values in the z-direction of the roughness profile, determined in accordance with DIN EN ISO 4287:2010-07.

The adhesive strength can be determined according to E DIN EN ISO 4624:2014-06: pull-off test to assess the adhesive strength or DIN EN ISO 2409:2013-06: cross cutting test. The porosity can be determined by means of mercury porosimetry or BET measurement according to DIN-ISO 9277.

The coating containing SiₓN_{y} is preferably produced in that an SiₓN_{y}-containing suspension is applied over the entire surface or at least in regions to the inner surface of the crucible and the moist SiₓN_{y}-containing coating produced in this way is dried.

The SiₓN_{y}-containing suspension preferably has a composition having the following components:

10% by weight to 60% by weight SiₓN_{y},

30% by weight to 80% by weight organic solvent or water,

0% by weight to 30% by weight silicon,

0.5% by weight to 10% by weight dispersant,

0.01% by weight to 0.2% by weight defoamer, and

0.05% by weight to 2% by weight organic binder,

wherein the proportions of the components add up to 100% by weight.

The SiₓN_{y}-containing suspension is preferably applied by means of a spraying method, a brushing method, a spreading method, and/or a dipping method. The crucible should have a temperature of preferably 10° C. to 200° C., preferably a temperature of 20° C. to 100° C. when applying the SiₓN_{y}-containing suspension.

A further preferred variant of the method according to the invention provides that after step a) and before step b), at least one seed plate, particularly as a base plate, is introduced into the crucible. This is used for the nucleation of the silicon in a direction perpendicular to the crucible bottom. This seed plate is preferably formed from mono- or multi-crystalline silicon, that is, consists or contains mono- or multi-crystalline silicon. The material of the seed plate preferably has an orientation (100, 110 or 111) perpendicular to the seed plate in the direction of crystal growth.

The dimensioning of the seed plate is specified by the surface of the crucible with regard to the maximum possible area. However, a smaller area of the seed plate is preferably chosen so that a plurality of seed plates can also be arranged in the crucible. The seed plates according to the invention may preferably be square in shape (for example, 10×10 cm, 20×20 cm, 30×30 cm), a rectangular shape (for example, 100 cm×10 cm, 100 cm×20 cm, 100×30 cm) or a circular shape (for example, having a 200 or 300 mm diameter). A plurality of seed plates should then cover the bottom surface of the crucible as well as possible. A further preferred embodiment provides that a plurality of seed plates are arranged in a grid on the bottom of the crucible, for example, as a 3×3 grid or 4×4 grid having a diameter of 200 or 300 mm for the round seed plates.

The thickness of the at least one seed plate is preferably in the range of 1 to 10 cm, particularly preferably in the range of 3 to 7 cm.

According to the invention, a crucible for producing particle-free and nitrogen-free silicon ingots by means of directional solidification is also provided, wherein the inner surface of the crucible has a coating containing SiₓN_{y} over the entire surface or at least in regions, on which a protective layer containing SiOₓ for reducing or avoiding the entry of nitrogen and SiₓN_{y} particle entry is deposited in the silicon.

According to the invention, it was found that the SiOₓ layer must lie in a certain thickness range, which essentially depends on the dissolution/erosion rate of the SiOₓ layer in the respective furnace/crystal growth process.

If the layer is applied too thinly, it can be completely eroded and the positive effect does not occur, since there is contact of the Si melt with the SiₓN_{y} layer. If the layer is applied too thick, cracks can form in the silicon block during cooling due to the above-mentioned solid bond and the different expansion coefficients of SiOₓ and silicon. A layer thickness of 200-500 μm after the crystallization process has proven to be ideal. The originally applied layer thickness should therefore be in the range of 200-500 μm+layer thickness eroded in the process. It is therefore preferred that the protective layer containing SiOₓ has a thickness of 10 to 2000 μm, particularly preferably 50 to 1000 μm.

A further preferred embodiment provides that the protective layer containing SiOₓ has a square mean roughness value R_{q} of 1 to 250 μm, preferably 5 to 150 μm.

It is further preferred that the protective layer containing SiOₓ has a porosity of 20 to 80%, preferably of 30% to 70% after coating the SiₓN_{y} layer.

According to the invention, a silicon ingot having a nitrogen concentration of <1E16 at/cm³, preferably <5E15 at/cm³, particularly preferably <1E15 at/cm³ is also provided.

The silicon block preferably has an SiₓN_{y} particle density of <10/cm³, preferably of <5/cm³.

The silicon ingot can preferably be produced by the method described above according to any one of claims 1 to 9.

The ingot preferably consists or consists essentially of monocrystalline, quasi-monocrystalline or multicrystalline silicon.

The subject according to the invention is to be described in more detail with the aid of the following FIGURES and examples, without restricting them to the specific forms shown here.

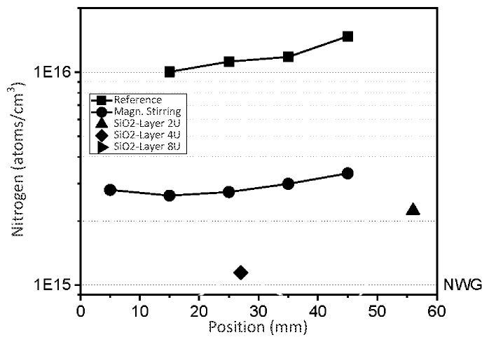

FIG. 1 uses a diagram to show the nitrogen concentration in a silicon ingot according to the invention over the ingot height, each measured in the ingot center

### EXEMPLARY EMBODIMENT

In a first exemplary embodiment, a series of laboratory crystallization experiments were carried out (Si initial weight 1.1 kg, ingot dimensions 100 mm in diameter, 60 mm in height).

First, a reference was grown without an SiO2 protective layer. The resulting nitrogen concentration in the ingot, measured by FTIR, is here [N]≥1E16 at/cm³ (see FIG. 1), which is in the range of the nitrogen solubility limit, thus leading to the formation of precipitates.

If a very thin SiO2 protective layer (2U) is now applied, the concentration over the major part of the block already falls below the detection limit of the FTIR measurement method of 1E15 at/cm³. A value of ^{˜}2E15 at/cm³ can only be measured at the end of the block, which is an indication of the dissolution of the SiO2 layer. With increased thickness (4U or 8U), practically no nitrogen can be measured using FTIR, that is, constantly below 1E15 at/cm³, and Si3N4 precipitation is reliably avoided. In addition, it can be assumed that no Si3N4 particles got into the melt, as otherwise they would have dissolved until nitrogen solubility was reached and nitrogen would therefore have to be detected. In the case of an SiO2 coating having a thickness of 20U, cracks occurred in the lower block bottom area due to the different thermal expansion of the SiO2 layer and the Si block.

In comparison to the experiments with the SiO2 layer, FIG. 1 shows a further experiment with forced melt convection. The nitrogen values show that the formation of precipitates cannot, however, completely avoid the entry of nitrogen.

1-29. (canceled)

30. A method for producing particle-free and nitrogen-free silicon ingots by directional solidification, in which
a) a crucible is provided, the inner surface of the crucible having a coating containing SiₓN_{y} over the entire surface or at least in regions, which coating is coated with a protective layer containing SiOₓ for reducing or avoiding the entry of nitrogen and entry of SiₓN_{y} particles into the silicon,
b) the crucible is filled with silicon raw material,
c) the silicon raw material is melted in the crucible to form a silicon melt, and
d) the silicon melt is subjected to a directional solidification, whereby particle-free and nitrogen-free silicon is formed.

31. The method according to claim 30, wherein the protective layer is applied to the SiₓN_{y}-containing coating by means of a spraying method, a brushing method, a spreading method and/or a dipping method of a suspension containing SiOₓ and the SiOₓ-containing moist protective layer produced in this way is dried.

32. The method according to claim 31, wherein the suspension contains 5 to 90% by weight SiOₓ, and 95 to 10% by weight of a suspending agent.

33. The method according to claim 30, wherein the protective layer is applied to the SiₓN_{y}-containing coating by a spraying method, a brushing method, a spreading method, and/or a dipping method of a suspension containing Si and the Si-containing moist protective layer produced in this way is dried and/or oxidized.

34. The method according to claim 33, wherein the suspension contains 5 to 90% by weight of Si and 95 to 10% by weight of a suspending agent.

35. The method according to claim 33, wherein the Si layer is oxidized under an air atmosphere or an inert gas atmosphere enriched with oxygen at a temperature of 800 and 1400° C. to form an SiOₓ layer.

36. The method according to claim 35, wherein the duration of the oxidation is in the range from 0.5 h to 12 h.

37. The method according to claim 31, wherein when the SiOₓ or Si-containing suspension is applied, the crucible or the coating containing SiₓN_{y} has a temperature of 10° C. to 200° C.

38. The method according to claim 30, wherein the SiOₓ has at least one of the following properties:
an iron content of 0 ppm to 5 ppm,
an aluminum content of 0 ppm to 20 ppm,
a content of metals other than iron and aluminum of 0 ppm to 5 ppm,
a particle size d50 of 0.05 to 100 μm,
a particle size d90 of 0.01 to 200 μm.

39. The method according to claim 30, wherein the crucible contains or consists of a material which is selected from the group consisting of SiC, C, BN, pBN, SiₓN_{y}, SiOₓ, and mixtures and combinations thereof.

40. The method according to claim 30, wherein the coating containing SiₓN_{y} has at least one of the following properties:
a content of up to 100% by weight, SiₓN_{y}
a thickness of 10 μm to 2500 μm,
a square mean roughness value R_{q} of 1 μm to 100 μm,
an adhesive strength on the crucible bottom of 0.5 MPa to 5 MPa, and
a porosity of 0.5% to 60%.

41. The method according to claim 30, wherein the coating containing SiₓN_{y} is produced in that an SiₓN_{y}-containing suspension is applied to the inner surface of the crucible and the moist SiₓN_{y}-containing coating produced in this way is dried.

42. The method according to claim 30, wherein the SiₓN_{y}-containing suspension has a composition having the following components:
10% by weight to 60% by weight SiₓN_{y},
30% by weight to 80% by weight organic solvent or water,
0% by weight to 30% by weight silicon,
0.5% by weight to 10% by weight dispersant,
0.01% by weight to 0.2% by weight defoamer, and
0.05% by weight to 2% by weight organic binder,
wherein the proportions of the components add up to 100% by weight.

43. The method according to claim 30, wherein
the SiₓN_{y}-containing suspension is applied by a spraying method, a brushing method, a spreading method, and/or a dipping method, and/or
the crucible has a temperature of 10° C. to 200° C. when applying the SiₓN_{y} containing suspension, and/or
the SiₓN_{y}-containing suspension is additionally applied to at least one further inner surface of the crucible.

44. The method according to claim 30, wherein after step a) and before step b), at least one seed plate, is arranged on the bottom of the crucible.

45. The method according to claim 44, wherein the at least one seed plate consists of or contains mono- or multi-crystalline silicon, wherein the at least one seed plate has an orientation perpendicular to the seed plate in the direction of crystal growth.

46. The method according to claim 40, wherein the at least one seed plate has a square shape, a rectangular shape, or a round shape, and/or the at least one seed plate has a thickness of 1 to 10 cm.

47. A crucible for producing particle-free and nitrogen-free silicon ingots by means of directional solidification, the inner surface of the crucible having a coating containing SiₓN_{y} over the entire surface or at least in regions, on which a protective layer containing SiOₓ for reducing or avoiding the entry of nitrogen and SiₓN_{y} particle entry is deposited in the silicon.

48. The crucible according to claim 47, wherein the protective layer containing SiOₓ has a thickness of 10 to 2000 μm.

49. The crucible according to claim 47, wherein the protective layer containing SiOₓ has a square mean roughness value R_{q} of 1 to 250 μm.

50. The crucible according to claim 47, wherein the protective layer containing SiOₓ has a porosity of 20 to 80% after coating the SiₓN_{y} layer.

51. The crucible according to claim 45, wherein the crucible has at least one seed plate at the bottom of the crucible.

52. The crucible according to the claim 51, wherein the at least one seed plate consists of or contains mono- or multi-crystalline silicon, wherein the at least one seed plate has an orientation perpendicular to the seed plate in the direction of crystal growth.

53. The crucible according to claim 51, wherein the at least one seed plate has a square shape, a rectangular shape, or a round shape, having a diameter of 200 or 300 mm, and/or the at least one seed plate has a thickness of 1 to 10 cm.

54. A silicon ingot having a nitrogen concentration of <1E16 at/cm³.

55. The silicon ingot according to claim 54, wherein the silicon ingot has an SiₓN_{y} particle density of <10/cm³.

56. A silicon ingot produced according to the method of claim 30 which has a nitrogen concentration of <1E16 at/cm³.

57. The silicon ingot according to claim 54, wherein the silicon ingot consists of single crystal, quasi-monocrystalline or multicrystalline silicon.

58. A method of producing silicon ingots by means of directional solidification, comprising utilizing the crucible according to claim 47.
